(19) United States
(12) Patent Application Publication
(10) Pub. No.: US 2022/0198244 A1
(43) Pub. Date: Jun. 23, 2022

(54) METHOD FOR DIAGNOSING OPEN-CIRCUIT FAULT OF SWITCHING TRANSISTOR OF SINGLE-PHASE HALF-BRIDGE FIVE-LEVEL INVERTER

(71) Applicant: WUHAN UNIVERSITY, Hubei (CN)

(72) Inventors: Yigang HE, Hubei (CN); Bolun DU, Hubei (CN); Jiajun DUAN, Hubei (CN); Lei Wang, Hubei (CN); Zhikai Xing, HUBEI (CN); Liulu HE, Hubei (CN)

(73) Assignee: WUHAN UNIVERSITY, Hubei (CN)

(21) Appl. No.: 17/503,354

(22) Filed: Oct. 17, 2021

(30) Foreign Application Priority Data
Dec. 18, 2020 (CN) 202011508386.9

(51) Int. Cl. G06N 3/04; G06K 9/00; G06K 9/62; G06F 30/3308; G06N 3/08; G01R 31/54

(52) U.S. Cl. CPC G06N 3/04; G06K 9/00536; G06K 9/6288; G06K 9/6255; G01R 31/54; G06K 9/6262; G06F 30/3308; G06N 3/08; G06K 9/6256

(57) ABSTRACT

A method for diagnosing an open-circuit fault of a switching transistor of a single-phase half-bridge five-level inverter is provided. It includes the following steps. A semi-physical experiment platform with a DSP controller and an RT-LAB real-time simulator as its core constructed, and an output side voltage is selected as a fault signal variable. Empirical mode decomposition is used to extract a fault feature vector, and then a HHT time-frequency diagram of the fault feature vector is extracted, a voltage signal is converted into spectrum data, and time-frequency diagram fuzzy sets corresponding to different fault types are obtained. Fusion of the time-frequency diagram fuzzy sets of the same fault type is performed to obtain a fusion image that contains more fault features. The fusion images corresponding to all fault types are inputted into the deep convolutional neural network for training and testing, and a fault diagnosis result is obtained.

### CROSS-REFERENCE TO RELATED APPLICATION

This application claims the priority benefit of China application serial no. 202011508386.9, filed on Dec. 18, 2020. The entirety of the above-mentioned patent application is hereby incorporated by reference herein and made a part of this specification.

### BACKGROUND

### Technical Field

This disclosure belongs to the field of power electronic circuit fault diagnosis, and in particular, relates to a method for diagnosing an open-circuit fault of a switching transistor of a single-phase half-bridge five-level inverter.

### Description of Related Art

Currently, with increasingly large number of power electronic switching devices and increase in circuit complexity, there is generally a large amount of signal data obtained during a long-term monitoring process. When a current conventional signal-based feature extraction method is dealing with the large amount of signal data, it usually compress the amount of data by sampling or directly discard a portion of signal details to generate a small-scale data set first, and then uses the data set for subsequent training and learning, and to establish a fault diagnosis model. In addition, a signal-based fault diagnosis method is extremely slow when processing a large amount of signal data, and when the diagnosis method is training and learning a large amount of feature data, it often results in issues such as invalid learning and weak generalization, therefore being unable to effectively identify the fault.

### SUMMARY

This disclosure provides a method for diagnosing an open-circuit fault of a switching transistor of a single-phase half-bridge five-level inverter, which combines a feature extraction algorithm, an image fusion algorithm, and a deep convolutional neural network classification algorithm. As compared to the conventional waveform signal-based fault diagnosis method, this method determines a fault of a power electronic circuit through identification of classification of a time-frequency diagram, increases data volume of the fault diagnosis, and improves accuracy of the fault diagnosis.

According to an aspect of the disclosure, a method for diagnosing an open-circuit fault of a switching transistor of a single-phase half-bridge five-level inverter is provided, which includes the following steps.

(1) A simulation model of a circuit to be diagnosed is established, label classification of fault types is performed according to number of switching transistors that have an open-circuit fault and their positions, and output side voltage data of the circuit under normal operation and having different open-circuit faults are collected as fault signal variables.

(2) Empirical mode decomposition (EMD) is performed on the fault signal variables to obtain intrinsic mode function (IMF) components to serve as a fault feature vector, and Hilbert spectrum analysis is adopted to extract a Hilbert-Huang Transform (HHT) time-frequency diagram of the fault feature vector.

(3) Image fusion of HHT time-frequency diagram fuzzy sets corresponding to the same type of open-circuit fault is performed to obtain a fusion image containing more fault feature information.

(4) A deep convolutional neural network is used to perform identification of classification of the fusion image, so as to realize an accurate diagnosis of the open-circuit fault of different switching transistors of the single-phase half-bridge five-level inverter.

In some embodiments, the Step (2) includes the following steps.

(2.1) The EMD decomposition of the fault signal variable is to directly perform decomposition according to a time scale feature of a voltage signal itself, and a complex voltage signal is decomposed into several complete, almost orthogonal IMF components.

(2.2) Each IMF component is divided into multiple segments evenly, and each segment is respectively converted into a HHT time-frequency diagram to obtain different HHT diagrams corresponding to different types of open-circuit fault. The multiple HHT time-frequency diagrams of the same type of open-circuit fault are recorded as a HHT time-frequency diagram fuzzy set of the same type of open-circuit fault.

In some embodiments, the Step (3) includes the following steps.

(3.1) A K-SVD algorithm is used to perform dictionary learning of all sub-regions of images to be fused, so as to obtain an over-complete dictionary D.

(3.2) A sparse vector is calculated using an orthogonal matching pursuit algorithm and the over-complete dictionary D.

(3.3) Sparse vector fusion of the HHT time-frequency diagram fuzzy sets corresponding to the same type of the open-circuit fault is completed based on a fusion rule of an absolute value of a largest element of the sparse vector, so as to obtain the fusion image.

In some embodiments, the Step (3.1) includes the following steps.

n HHT time-frequency diagrams corresponding to each fault signal variables serve as an input, and a sliding window technique is adopted to divide each time-frequency image into N blocks {Zₘⁱ, m=1, 2, . . . , n}ᵢ₌₁^{N}, respectively represented as {Z₁ⁱ}ᵢ₌₁^{N}, {Z₂ⁱ}ᵢ₌₁^{N}, . . . , {Zₘⁱ}ᵢ₌ₘ^{N}, . . . , {Zₙⁱ}ᵢ₌ₙ^{N}.

Each vector of {Zₘⁱ, m=1, 2, . . . , n} is converted into a column vector {Vₘⁱ, m=1, 2, . . . , n} using dictionary sorting, and then mean of each vector is normalized to zero, so as to obtain {\hat{V}ₘⁱ, m=1, 2, . . . , n}ᵢ₌₁^{N}, where \hat{V}ₘⁱ=Vₘⁱ−V̅ₘⁱ·1, 1 represents an n×1 vector and V̅ₘⁱ represents an average value of all elements in Vₘⁱ. {Vₘⁱ, m=1, 2, . . . , n}ᵢ₌₁^{N} serves as a training sample set, and the K-SVD algorithm is adopted to train a selected sample to be the over-complete dictionary D.

In some embodiments, the Step (3.2) includes the following step.

A sparse coefficient αₘⁱ corresponding to \hat{V}ₘⁱ is calculated using the orthogonal matching pursuit algorithm and the over-complete dictionary D, where

$${α}_{m}^{i} = arg {min}_{α} {‖ α ‖}_{0} s . t . {‖ {\hat{V}}_{m}^{i} - D α ‖}_{2} < ɛ ,$$

ε is a preset threshold.

In some embodiments, the Step (3.3) includes the following steps.

A fusion sparse vector α_{F}ⁱ is obtained from a rule

$${α}_{F}^{i} = \{ \begin{matrix}{α}_{A}^{i} & if {‖ {α}_{A}^{i} ‖}_{1} > {‖ {α}_{m}^{i} ‖}_{1} \\ {α}_{m}^{i} & otherwise\end{matrix} , m = 1 , 2 , … , n ,$$

where α_{A}ⁱ represents a random sparse coefficient.

A fusion sparse coefficient V_{F}ⁱ of the fusion image is obtained through V_{F}ⁱ=Dα_{F}ⁱ+V̅_{F}ⁱ·1, where V̅_{F}ⁱ represents an average value of all elements in V_{F}ⁱ.

All fusion sparse coefficients {V_{F}ⁱ}ᵢ₌₁^{N} are obtained through repeating the above steps for all image blocks {Zₘⁱ}ᵢ₌₁^{N}, a new image block Z_{F}ⁱ is reconstructed using the over-complete dictionary D and the fusion sparse coefficient V_{F}ⁱ, and all original image blocks Zₘⁱ are replaced by all new image blocks Z_{F}ⁱ, so as to obtain a fusion image S_{F}.

In some embodiments, the Step (4) includes the following steps.

(4.1) A data set of the labeled fusion image serves as an input of the deep convolutional neural network, and the data set of the labeled fusion image is divided into a training set and a test set.

(4.2) The deep convolutional neural network is adopted to classify the fusion images of the different fault types. The deep convolutional neural network is composed of an input layer, several convolutional layers, activation layers, pooling layers, and fully connected layers.

(4.3) A non-linear activation function and a non-linear loss function are selected. The deep convolutional neural network adopts a structure based on dynamic growth, determines an appropriate convolutional layer parameter, a pooling layer parameter, and a number of full connection layers using a network structure optimization method of increasing number of the convolutional layers/pooling layers and dropout technique, learns convolutional features of the fusion images of the same fault type, and summarizes key common features.

(4.4) A convolution kernel is selected, and fault diagnosis results of different deep convolutional neural networks are compared finally.

According to another aspect of the disclosure, a system for diagnosing an open-circuit fault of a switching transistor of a single-phase half-bridge five-level inverter is provided, which includes the following.

A data sampling module, which is configured to establish a simulation model of a circuit to be diagnosed, performs label classification of fault types according to number of switching transistors that have an open-circuit fault and their positions, and collect output side voltage data of the circuit under normal operation and having different open-circuit faults as fault signal variables.

A data processing module, which is configured to perform empirical mode decomposition (EMD) on the fault signal variable to obtain intrinsic mode function (IMF) components to serve as a fault feature vector, and to adopt Hilbert spectrum analysis to extract a Hilbert-Huang Transform (HHT) time-frequency diagram of the fault feature vector.

A feature fusion module, which is configured to perform image fusion of HHT time-frequency diagram fuzzy sets corresponding to the same type of open-circuit fault, so as to obtain a fusion image containing more fault feature information.

A training and testing module, which is configured to perform identification of classification of the fusion image by using the deep convolutional neural network, so as to realize an accurate diagnosis of the open-circuit fault of different switching transistors of the single-phase half-bridge five-level inverter.

According to another aspect of the disclosure, a computer-readable storage medium having a computer program stored thereon is also provided. When the computer program is executed by a processor, the steps of any one of the above-mentioned methods are realized.

In general, compared to the related art, the above technical solutions provided by the disclosure have the following advantages.

The disclosure innovatively converts electrical signal parameter data of each key component of the single-phase half-bridge five-level inverter when it fails into a time-frequency diagram through a time-frequency analysis method, which is configured to characterize different fault categories and provide local information on signal parameters in time domain and frequency domain. Then, the fusion image is combined to fuse complementary information of different time-frequency diagrams in the same fault category, so that the fusion image contains more fault features. With the rapid development of deep learning, deep convolutional neural network as one of the most effective deep learning algorithms, it may automatically learn abstract representation features of original data, and may overcome issues such as ineffective learning and weak generalization of shallow networks in fault diagnosis application. Therefore, the disclosure adopts a deep convolutional neural network-based method to identify the fault of a single-phase half-bridge five-level inverter, and uses the time-frequency diagram fuzzy sets corresponding to each key device fault to serve as the input of the network, and perform comparative learning of the key common features through the several convolutional layers, pooling layers, activation layers, and fully connected layers to identify different fault categories, which can greatly improve the accuracy of fault diagnosis.

### BRIEF DESCRIPTION OF THE DRAWINGS

FIG. 1 is a schematic flowchart of a method provided by an embodiment of the disclosure.

FIG. 2 is a topology diagram of a single-phase half-bridge five-level inverter provided by an embodiment of the disclosure.

FIG. 3 is a schematic diagram of a fault feature extraction method provided by an embodiment of the disclosure, in which (a) EMD decomposition process and (b) HHT time-frequency diagram of an output side voltage signal under normal operation is shown.

FIG. 4 is a schematic diagram of a fault feature fusion method provided by an embodiment of the disclosure.

FIG. 5 is a comparison diagram of diagnostic results of various types of deep convolutional neural networks (LeNet-5, AlexNet, VGG-16, VGG-19, GoogLeNet, ResNet-18, ResNet-50, ResNet-152) according to an embodiment of the disclosure.

### DESCRIPTION OF THE EMBODIMENTS

In order to enhance comprehension of the objectives, technical solutions, and advantages of the disclosure, the disclosure is further described in detail as follows with reference to accompanying drawings and embodiments. It should be understood that the specific embodiments described here are only used to explain the disclosure, and are not meant to limit the disclosure. In addition, the technical features involved in the various embodiments of the disclosure described below may be combined with each other as long as they are not in conflict with each other.

The disclosure is described in detail as follows using an open-circuit fault diagnosis of switching transistor of a single-phase half-bridge five-level inverter as an example, but the method of the disclosure is not limited to a single-phase half-bridge five-level inverter, and may also be applied to fault diagnosis of other circuits.

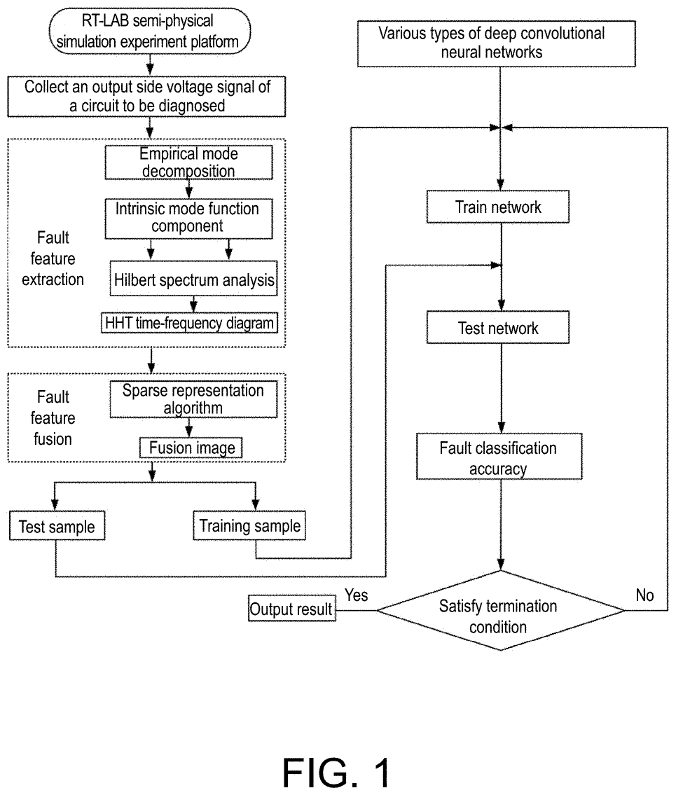

As shown in FIG. 1, FIG. 1 is a schematic flowchart of a method for diagnosing an open-circuit fault of a switching transistor of a single-phase half-bridge five-level inverter provided by an embodiment of the disclosure, which includes the following steps.

(1) A simulation model of the single-phase half-bridge five-level inverter is established, and an output side voltage is selected as a fault feature variable. Label classification of fault types is performed according to number of power electronic switching devices that have an open-circuit fault and their positions, which is described in details below.

(1.1) A disadvantage of the existing commonly used non-real-time offline simulation method is that there is a big jump in a process from offline simulation to an actual prototype, and there are many uncertain factors. Therefore, in the embodiment of the disclosure, a semi-physical experiment platform with a Digital Signal Processing (DSP) controller and an RT-LAB real-time simulator as its core is built, which is more controllable, more repeatable, and non-destructive under a premise of being close to a real experiment.

Firstly, MATLAB/Simulink is used to establish models such as an entire circuit topology and a controller, and then RT-LAB is used to run them in real-time to complete system design. At a hardware design stage of the real controller, a RT-LAB semi-physical simulation platform is used to connect to a real DSP control platform, so as to complete development of control strategy.

Secondly, after completion of the development of the real controller, the RT-LAB platform is used to set up different fault tests for the single-phase half-bridge five-level inverter. For example, construct a fault feature library covering different switching devices and multiple open-circuit faults, record faulty elements, fault types, and collect output signal data.

Finally, fault feature extraction, fault feature fusion, and the fault diagnosis method are verified in the MATLAB/Simulink simulation environment and the DSP RT-LAB semi-physical experiment environment based on the output signal data.

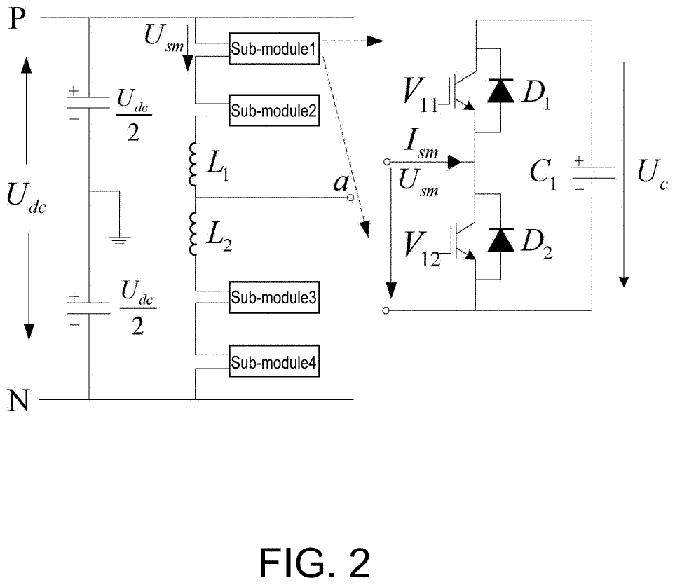

(1.2) A circuit simulation topology diagram of the single-phase half-bridge five-level inverter is shown in FIG. 2, which is consist of two upper and lower bridge arms to form a phase unit. Each bridge arm contains 2 sub-modules and a bridge arm inductance, and in-between the upper bridge arm inductance L₁ and the lower bridge arm inductance L₂ serves as an AC output terminal. A input terminal of the two sub-modules in series of the upper bridge arm forms a positive bus terminal P, and an output terminal of the two sub-modules in series of the lower bridge arm forms a negative bus terminal N, thereby forming a DC bus side, which may be connected to a DC voltage source or a DC load etc. A voltage midpoint O of the DC bus has to form a loop with the AC output terminal of the bridge arm, so as to exchange power on the AC and DC sides. Each sub-module is composed of two switching transistors with anti-parallel diodes connected in series, and a DC capacitor C₁ is connected in parallel with the two switching transistors. In a structure of the sub-module, the DC capacitor C₁ is equivalent to a voltage source, which stores and releases electrical energy through continuous charging and discharging. In FIG. 2, Uₛₘ is an output voltage of the sub-module, I_{Sm} is an input current of the sub-module, and Uₒ is a capacitor voltage of the sub-module. The two bridge arms have 8 types of open-circuit faults, and when inclusive of a normal operating state, there are 9 classifications. A relationship between a switching state of the single-phase half-bridge five-level inverter and the fault types is shown in Table 1, where V₁₁ OC and V₁₂ OC respectively represent an open-circuit fault of power transistors V11 and V12. And the output side voltage is selected as a fault signal variable.

TABLE 1
Fault category and label

| Fault classification | Label | Fault code |
|---|---|---|
| Normal operation | [1, 0, 0, 0, 0, 0, 0, 0, 0]^{T} | 1 |
| V₁₁ OC | [0, 1, 0, 0, 0, 0, 0, 0, 0]^{T} | 2 |
| V₁₂ OC | [0, 0, 1, 0, 0, 0, 0, 0, 0]^{T} | 3 |
| V₂₁ OC | [0, 0, 0, 1, 0, 0, 0, 0, 0]^{T} | 4 |
| V₂₂ OC | [0, 0, 0, 0, 1, 0, 0, 0, 0]^{T} | 5 |
| V₃₁ OC | [0, 0, 0, 0, 0, 1, 0, 0, 0]^{T} | 6 |
| V₃₂ OC | [0, 0, 0, 0, 0, 0, 1, 0, 0]^{T} | 7 |
| V₄₁ OC | [0, 0, 0, 0, 0, 0, 0, 1, 0]^{T} | 8 |
| V₄₂ OC | [0, 0, 0, 0, 0, 0, 0, 0, 1]^{T} | 9 |

(2) Empirical mode decomposition (EMD) is performed on the fault signal variable to obtain intrinsic mode function (IMF) components, which serves as a fault feature vector, and Hilbert spectrum analysis is adopted to extract a Hilbert-Huang Transform (HHT) time-frequency diagram of the fault feature vector.

In Step (2), a fault feature extraction method of the single-phase half-bridge five-level inverter based on time-frequency diagram analysis is able to extract a time-frequency diagram fuzzy set that accurately characterize various types of faults, which is described in detail as follows.

(2.1) EMD decomposition is performed on the output side voltage. The EMD does not has to specify a basis function, instead it performs decomposition directly according to a time scale feature of the signal itself, and decomposes an output side voltage signal into several complete, almost orthogonal IMF components and a sum of residual components. Each stage of IMF components corresponds to a vibration mode of a specific signal of discrete frequency. The EMD method decomposes the output voltage signal as follows:

$$x ( t ) = {\sum }_{i = 1}^{n} {c}_{i} ( t ) + r ( t ) \qquad ( 1 )$$

where each stage of IMF components cᵢ(t) contains different time feature scales of the output side voltage signal, and a residual difference component r(t) represents an average trend of the output side voltage signal. Therefore, feature information of a power electronic circuit fault may be extracted from the IMF components of the circuit output signal.

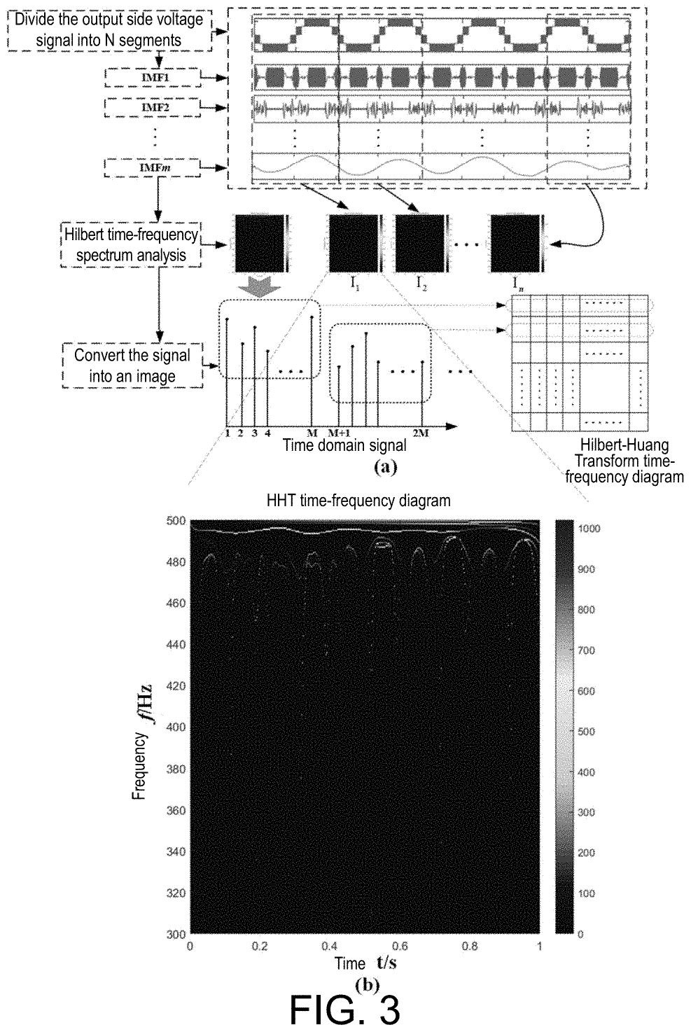

(2.2) A EMD decomposition process of the output side voltage signal of the single-phase half-bridge five-level inverter in normal operation is shown in FIG. 3(a). Each stage of the IMF components is decomposed into multiple segments, and then the HHT time-frequency diagram of each segment is extracted by the Hilbert-Huang Transform algorithm, the waveform signal is converted into spectrum data, where different fault types corresponds to different HHT diagrams. Multiple HHT time-frequency diagrams are obtained for the same fault type, which are recorded as the time-frequency diagram fuzzy set corresponding to a certain type of fault. The HHT time-frequency diagram under normal operating conditions is shown in FIG. 3(b).

(3) Image fusion of the HHT time-frequency diagram fuzzy sets corresponding to the same type of open-circuit fault is performed to obtain a fusion image containing more fault feature information.

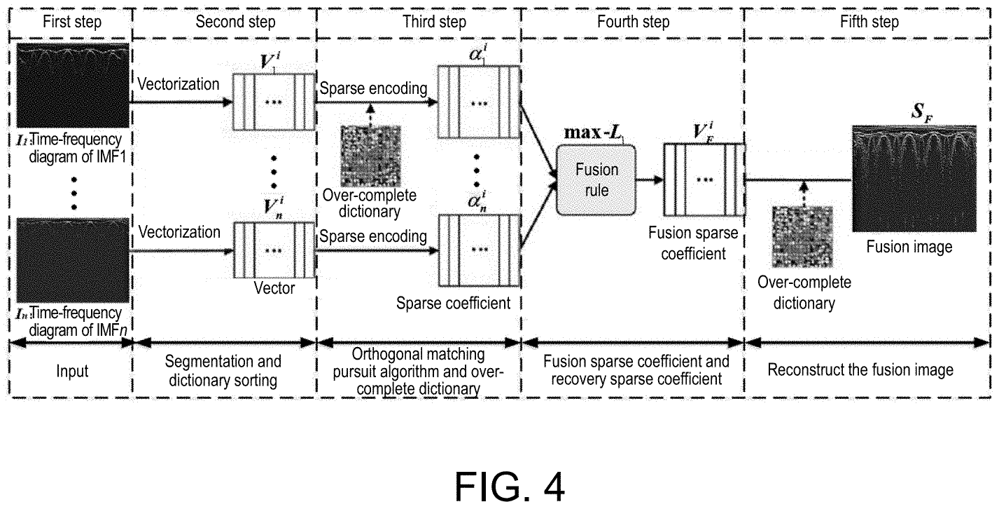

Multiple HHT time-frequency images in the time-frequency diagram fuzzy set usually contain some complementary information, and a fusion image containing more fault feature information may be obtained through fusion. FIG. 4 shows a principle diagram of the fusion process, which specifically includes the following steps.

(3.1) n HHT time-frequency diagrams corresponding to each fault signal variable serve as an input, and a sliding window technique is adopted to divide each time-frequency image into N blocks {Zₘⁱ, m=1, 2, . . . n}ᵢ₌₁^{N}, respectively represented as {Z₁ⁱ}ᵢ₌₁^{N}, {Z₂ⁱ}ᵢ₌₂^{N}, . . . , {Zₘⁱ}ᵢ₌ₘ^{N}, . . . , {Zₙⁱ}ᵢ₌ₙ^{N}.

(3.2) Each vector of {Zₘⁱ, m=1, 2, . . . , n} is converted into a column vector {Vₘⁱ, m=1, 2, . . . , n} using dictionary sorting, and then mean of each vector is normalized to zero, so as to obtain {\hat{V}ₘⁱ, m=1, 2, . . . , n}ᵢ₌₁^{N}, where

\hat{V}ₙⁱ=Vₘⁱ−V̅ₘⁱ·1 (2)

where 1 represents an n×1 vector and V̅ₘⁱ represents an average value of all elements in Vₘⁱ.

(3.3) {\hat{V}ₘⁱ, m=1, 2, . . . , n}ᵢ₌₁^{N} serves as a training sample set, and the K-SVD algorithm is adopted to train a selected sample to be the over-complete dictionary D. A sparse coefficient αₘⁱ corresponding to \hat{V}ₘⁱ is calculated using the orthogonal matching pursuit algorithm and the over-complete dictionary D, where

$${α}_{m}^{i} = arg {min}_{α} {‖ α ‖}_{0} s . t . {‖ {\hat{V}}_{m}^{i} - D α ‖}_{2} < ɛ , \qquad ( 3 )$$

where ε is a preset threshold.

(3.4) Use a “max-L₁” rule to fuse αₘⁱ, so as to obtain a fusion sparse vector α_{F}ⁱ:

$${α}_{F}^{i} = \{ \begin{matrix}{α}_{A}^{i} & if {‖ {α}_{A}^{i} ‖}_{1} > {‖ {α}_{m}^{i} ‖}_{1} \\ {α}_{m}^{i} & otherwise\end{matrix} , m = 1 , 2 , … , n , \qquad ( 4 )$$

where α_{A}ⁱ represents a random sparse coefficient.

Subsequently, a fusion sparse coefficient V_{F}ⁱ of the fusion image is obtained, V̅_{F}ⁱ represents an average value of all elements in V_{F}ⁱ:

V_{F}ⁱ=Dα_{F}ⁱ+V̅_{F}ⁱ·1 (5)

(3.5) All fusion sparse coefficients {V_{F}ⁱ}ᵢ₌₁^{N} are obtained through repeating the above steps for all image blocks {Zₘⁱ}ᵢ₌₁^{N}, a new image block Z_{F}ⁱ is reconstructed using the over-complete dictionary D and the fusion sparse coefficient V_{F}ⁱ, and all original image blocks Zₘⁱ are replaced by all new image blocks Z_{F}ⁱ, so as to obtain a fusion image S_{F}.

(4) A deep convolutional neural network is used to perform identification of classification of the fusion image S_{F}, so as to realize an accurate diagnosis of the different faults of the single-phase half-bridge five-level inverter.

In the embodiment of the disclosure, a deep convolutional neural network such as LeNet, AlexNet, ResNet, VGGNet, GoogLeNet, is adopted for fault classification, which specifically includes the following steps.

(4.1) A network framework of the deep convolutional neural network is an open source LeNet, AlexNet, ResNet, VGGNet, and GoogLeNet framework in Caffe. In the experiment, the CPU is Inter® Core™ i7-4790 CPU @ 3.60 GHz, and the GPU is NVIDIA GeForce GTX 750 Ti. In the embodiment of the disclosure, on a basis that a fusion image may be used to characterize different fault types, a data set of the labeled fusion image serves as an input of the deep convolutional neural network and is divided into a training set and a test set.

(4.2) The deep convolutional neural network is composed of an input layer, several convolutional layers, activation layers, pooling layers, and fully connected layers. The appropriate numbers of the convolutional layers, pooling layers and full connection layers for fault classification is determined. A number of neurons in the fully connected layers may be modified. As there are 9 fault types in the embodiment of the disclosure, the number of neurons in a final fully connected layer is modified to 9. In order to prevent over-fitting, reduce errors, enhance features, and speed up convergence, an appropriate non-linear activation function is selected in the fault diagnosis test, such as Sigmoid function, ReLU function, ELU function, and tan h function. An appropriate loss function is selected in the fault diagnosis test, such as 0-1 loss function, absolute value loss function, square loss function, variance loss function, and cross entropy loss function.

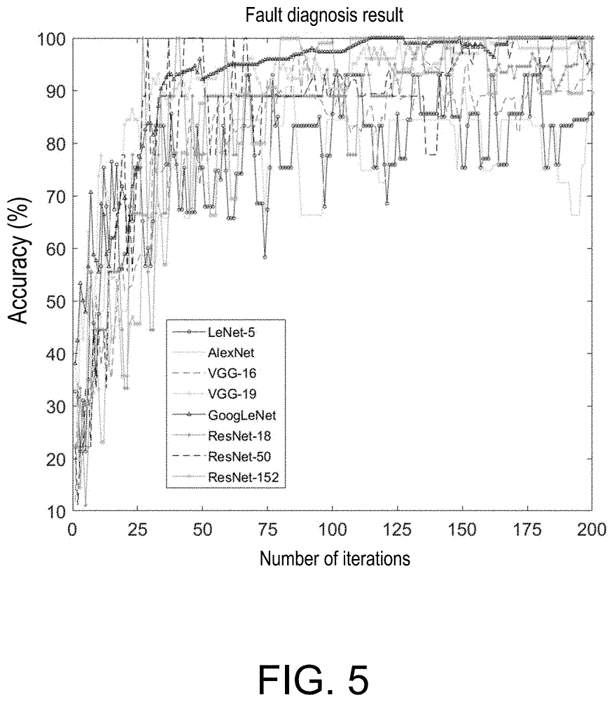

(4.3) The deep convolutional neural network adopts a structure based on dynamic growth, determines an appropriate convolutional layer parameter, a pooling layer parameter, and a number of full connection layers using a network structure optimization method of increasing number of the convolutional layers/pooling layers and dropout technique, learns convolutional features of the fusion images of the same fault type, and summarizes key common features. In the fault diagnosis test, an appropriate convolution kernel is selected, such as an identity kernel, an edge detection kernel, a sharpness filter kernel, and a Gaussian blur kernel. FIG. 5 shows that the fault diagnosis result obtained by adopting the LeNet, AlexNet, ResNet, VGGNet, GoogLeNet, and other deep convolutional neural networks in the embodiment of the disclosure has higher accuracy.

The disclosure further provides a system for diagnosing an open-circuit fault of a switching transistor of a single-phase half-bridge five-level inverter, which includes the following.

A data sampling module, which is configured to establish a simulation model of a single-phase half-bridge five-level inverter, performs label classification of fault types according to number of switching transistors that have an open-circuit fault and their positions, and collect output side voltage data of the circuit under normal operation and having different open-circuit faults as fault signal variables.

A data sampling module, which is configured to establish a simulation model of a circuit to be diagnosed, performs label classification of fault types according to number of switching transistors that have an open-circuit fault and their positions, and collect output side voltage data of the circuit under normal operation and having different open-circuit faults as fault signal variables.

A data processing module, which is configured to perform empirical mode decomposition (EMD) on the fault signal variable to obtain intrinsic mode function (IMF) components to serve as a fault feature vector, and to adopt Hilbert spectrum analysis to extract a Hilbert-Huang Transform (HHT) time-frequency diagram of the fault feature vector.

A feature fusion module, which is configured to perform image fusion of the HHT time-frequency diagram fuzzy sets corresponding to the same type of the open-circuit fault, so as to obtain a fusion image containing more fault feature information.

A training and testing module, which is configured to perform identification of classification of the fusion image by using the deep convolutional neural network, so as to realize an accurate diagnosis of the open-circuit fault of different switching transistors of the single-phase half-bridge five-level inverter.

Reference may be made to the description of the foregoing method embodiment for the specific implementation of each module, which is not repeated here in the embodiment of the disclosure.

According to another aspect of the present invention, there is provided a computer-readable storage medium on which a computer program is stored. When the computer program is executed by a processor, the method for diagnosing an open-circuit fault of a switching transistor of the single-phase half-bridge five-level inverter in the method embodiment is realized.

It should be noted that according to implementation requirements, each step/component described in the application may be split into more steps/components, or two or more steps/components or partial operations of the steps/components may be combined into new steps/components, so as to realize the purpose of the disclosure.

Although the disclosure has been described with reference to the above-mentioned embodiments, it is not intended to be exhaustive or to limit the disclosure to the precise form or to exemplary embodiments disclosed. It is apparent to one of ordinary skill in the art that modifications to the described embodiments may be made without departing from the spirit and the scope of the disclosure. Accordingly, the scope of the disclosure is defined by the claims appended hereto and their equivalents in which all terms are meant in their broadest reasonable sense unless otherwise indicated.

What is claimed is:

1. A method for diagnosing an open-circuit fault of a switching transistor of a single-phase half-bridge five-level inverter, comprising:
establishing a simulation model of a circuit to be diagnosed, performing label classification of fault types according to number of switching transistors that have an open-circuit fault and their positions, and collecting output side voltage data of the circuit under normal operation and having different open-circuit faults as fault signal variables;
performing empirical mode decomposition (EMD) on the fault signal variables to obtain intrinsic mode function (IMF) components to serve as a fault feature vector, and adopting Hilbert spectrum analysis to extract a Hilbert-Huang Transform (HHT) time-frequency diagram of the fault feature vector;
performing image fusion of HHT time-frequency diagram fuzzy sets corresponding to a same type of the open-circuit fault to obtain a fusion image containing more fault feature information; and
performing identification of classification of the fusion image using a deep convolutional neural network, so as to realize an accurate diagnosis of the open-circuit fault of different switching transistors of the single-phase half-bridge five-level inverter.

2. The method according to claim 1, wherein performing the EMD on the fault signal variables to obtain the IMF components to serve as the fault feature vector, and adopting the Hilbert spectrum analysis to extract the HHT time-frequency diagram of the fault feature vector comprises:
directly performing decomposition according to a time scale feature of a voltage signal itself, and decomposing a complex voltage signal into the several complete and orthogonal IMF components during the EMD of the fault signal variable; and
dividing each of the IMF components into multiple segments evenly, respectively converting each segment into the HHT time-frequency diagram to obtain different HHT diagrams corresponding to different types of the open-circuit fault, wherein the multiple HHT time-frequency diagrams of the same type of the open-circuit fault are recorded as a HHT time-frequency diagram fuzzy set of the same type of the open-circuit fault.

3. The method according to claim 2, wherein performing the image fusion of the HHT time-frequency diagram fuzzy sets corresponding to the same type of the open-circuit fault to obtain the fusion image containing more fault feature information comprises:
performing dictionary learning of all sub-regions of images to be fused using a K-SVD algorithm, so as to obtain an over-complete dictionary D;
calculating a sparse vector using an orthogonal matching pursuit algorithm and the over-complete dictionary D; and
completing sparse vector fusion of the HHT time-frequency diagram fuzzy sets corresponding to the same type of the open-circuit fault based on a fusion rule of an absolute value of a largest element of the sparse vector, so as to obtain the fusion image.

4. The method according to claim 3, wherein performing the dictionary learning of all the sub-regions of the images to be fused using the K-SVD algorithm, so as to obtain the over-complete dictionary D comprises:
using n HHT time-frequency diagrams corresponding to each of the fault signal variables to serve as an input, and adopting a sliding window technique to divide each time-frequency image into N blocks {Zₘⁱ, m=1, 2, . . . , n}, respectively represented as {Z₁ⁱ}ᵢ₌₁^{N}, {Z₂ⁱ}ᵢ₌₂^{N}, . . . , {Zₘⁱ}ᵢ₌ₘ^{N}, . . . , {Zₙⁱ}ᵢ₌ₙ^{N};
converting each vector of {Zₘⁱ, m=1, 2, . . . , n} into a column vector {Vₘⁱ, m=1, 2, . . . , n} using dictionary sorting, and then normalizing mean of the each vector to zero, so as to obtain {\hat{V}ₘⁱ, m=1, 2, . . . n}ᵢ₌₁^{N}, where \hat{V}ₘⁱ=Vₘⁱ−V̅ₘⁱ·1, 1 represents an n×1 vector and V̅ₘⁱ represents an average value of all elements in Vₘⁱ; and
using {\hat{V}ₘⁱ, m=1, 2, . . . n}ᵢ₌₁^{N} to serve as a training sample set, and adopting the K-SVD algorithm to train a selected sample to be the over-complete dictionary D.

5. The method according to claim 4, wherein calculating the sparse vector using the orthogonal matching pursuit algorithm and the over-complete dictionary D comprises:
calculating a sparse coefficient αₘⁱ corresponding to \hat{V}ₘⁱ using the orthogonal matching pursuit algorithm and the over-complete dictionary D, where
$${α}_{m}^{i} = arg {min}_{α} {‖ α ‖}_{0} s . t . {‖ {\hat{V}}_{m}^{i} - D α ‖}_{2} < ɛ ,$$
ε is a preset threshold.

6. The method according to claim 5, wherein completing the sparse vector fusion of the HHT time-frequency diagram fuzzy sets corresponding to the same type of the open-circuit fault based on the fusion rule of the absolute value of the largest element of the sparse vector, so as to obtain the fusion image comprises:
obtaining a fusion sparse vector α_{F}ⁱ from a rule
$${α}_{F}^{i} = \{ \begin{matrix}{α}_{A}^{i} & if {‖ {α}_{A}^{i} ‖}_{1} > {‖ {α}_{m}^{i} ‖}_{1} \\ {α}_{m}^{i} & otherwise\end{matrix} , m = 1 , 2 , … , n ,$$
where α_{A}ⁱ represents a random sparse coefficient;
obtaining a fusion sparse coefficient V_{F}ⁱ of the fusion image through V_{F}ⁱ=Dα_{F}ⁱ+V̅_{F}ⁱ·1, where V̅_{F}ⁱ represents an average value of all elements in V_{F}ⁱ; and
obtaining all fusion sparse coefficients {V_{F}ⁱ}ᵢ₌₁^{N} through repeating the above steps for all image blocks {Zₘⁱ}ᵢ₌₁^{N}, reconstructing a new image block Z_{F}ⁱ using the over-complete dictionary D and the fusion sparse coefficient V_{F}ⁱ, and replacing all original image blocks Zₘⁱ with all new image blocks Z_{F}ⁱ, so as to obtain a fusion image S_{F}.

7. The method according to claim 1, wherein performing the identification of the classification of the fusion image using the deep convolutional neural network, so as to realize the accurate diagnosis of the open-circuit fault of the different switching transistors of the single-phase half-bridge five-level inverter comprises:
using a data set of the labeled fusion image to serve as an input of the deep convolutional neural network, and dividing the data set of the labeled fusion image into a training set and a test set;
adopting the deep convolutional neural network to classify the fusion images of the different fault types, wherein the deep convolutional neural network is composed of an input layer, a plurality of convolutional layers, activation layers, pooling layers, and fully connected layers;
selecting a non-linear activation function and a non-linear loss function, wherein the deep convolutional neural network adopts a structure based on dynamic growth, determines an appropriate convolutional layer parameter, a pooling layer parameter, and a number of full connection layers using a network structure optimization method of increasing number of the convolutional layers/pooling layers and dropout technique, learns convolutional features of the fusion images of the same type of the open-circuit fault, and summarizes key common features; and
selecting a convolution kernel, and finally comparing fault diagnosis results of different deep convolutional neural networks.

8. A system for diagnosing an open-circuit fault of a switching transistor of a single-phase half-bridge five-level inverter, comprising:
a data sampling module, configured to establish a simulation model of a circuit to be diagnosed, performs label classification of fault types according to number of switching transistors that have an open-circuit fault and their positions, and collect output side voltage data of the circuit under normal operation and having different open-circuit faults as fault signal variables;
a data processing module, configured to perform empirical mode decomposition (EMD) on the fault signal variable to obtain intrinsic mode function (IMF) components to serve as a fault feature vector, and to adopt Hilbert spectrum analysis to extract a Hilbert-Huang Transform (HHT) time-frequency diagram of the fault feature vector;
a feature fusion module, configured to perform image fusion of HHT time-frequency diagram fuzzy sets corresponding to the same type of the open-circuit fault, so as to obtain a fusion image containing more fault feature information; and
a training and testing module, configured to perform identification of classification of the fusion image by using a deep convolutional neural network to realize an accurate diagnosis of the open-circuit fault of different switching transistors of the single-phase half-bridge five-level inverter.

9. A computer-readable storage medium, with a computer program stored thereon, wherein the computer program implements steps of the method for diagnosing the open-circuit fault of the switching transistors of the single-phase half-bridge five-level inverter according to claim 1 when the computer program is executed by a processor.

10. The method according to claim 2, wherein performing the identification of the classification of the fusion image using the deep convolutional neural network, so as to realize the accurate diagnosis of the open-circuit fault of the different switching transistors of the single-phase half-bridge five-level inverter comprises:
using a data set of the labeled fusion image to serve as an input of the deep convolutional neural network, and dividing the data set of the labeled fusion image into a training set and a test set;
adopting the deep convolutional neural network to classify the fusion images of the different fault types, wherein the deep convolutional neural network is composed of an input layer, a plurality of convolutional layers, activation layers, pooling layers, and fully connected layers;
selecting a non-linear activation function and a non-linear loss function, wherein the deep convolutional neural network adopts a structure based on dynamic growth, determines an appropriate convolutional layer parameter, a pooling layer parameter, and a number of full connection layers using a network structure optimization method of increasing number of the convolutional layers/pooling layers and dropout technique, learns convolutional features of the fusion images of the same type of the open-circuit fault, and summarizes key common features; and
selecting a convolution kernel, and finally comparing fault diagnosis results of different deep convolutional neural networks.

11. The method according to claim 3, wherein performing the identification of the classification of the fusion image using the deep convolutional neural network, so as to realize the accurate diagnosis of the open-circuit fault of the different switching transistors of the single-phase half-bridge five-level inverter comprises:
using a data set of the labeled fusion image to serve as an input of the deep convolutional neural network, and dividing the data set of the labeled fusion image into a training set and a test set;
adopting the deep convolutional neural network to classify the fusion images of the different fault types, wherein the deep convolutional neural network is composed of an input layer, a plurality of convolutional layers, activation layers, pooling layers, and fully connected layers;
selecting a non-linear activation function and a non-linear loss function, wherein the deep convolutional neural network adopts a structure based on dynamic growth, determines an appropriate convolutional layer parameter, a pooling layer parameter, and a number of full connection layers using a network structure optimization method of increasing number of the convolutional layers/pooling layers and dropout technique, learns convolutional features of the fusion images of the same type of the open-circuit fault, and summarizes key common features; and
selecting a convolution kernel, and finally comparing fault diagnosis results of different deep convolutional neural networks.

12. The method according to claim 4, wherein performing the identification of the classification of the fusion image using the deep convolutional neural network, so as to realize the accurate diagnosis of the open-circuit fault of the different switching transistors of the single-phase half-bridge five-level inverter comprises:
using a data set of the labeled fusion image to serve as an input of the deep convolutional neural network, and dividing the data set of the labeled fusion image into a training set and a test set;
adopting the deep convolutional neural network to classify the fusion images of the different fault types, wherein the deep convolutional neural network is composed of an input layer, a plurality of convolutional layers, activation layers, pooling layers, and fully connected layers;
selecting a non-linear activation function and a non-linear loss function, wherein the deep convolutional neural network adopts a structure based on dynamic growth, determines an appropriate convolutional layer parameter, a pooling layer parameter, and a number of full connection layers using a network structure optimization method of increasing number of the convolutional layers/pooling layers and dropout technique, learns convolutional features of the fusion images of the same type of the open-circuit fault, and summarizes key common features; and
selecting a convolution kernel, and finally comparing fault diagnosis results of different deep convolutional neural networks.

13. The method according to claim 5, wherein performing the identification of the classification of the fusion image using the deep convolutional neural network, so as to realize the accurate diagnosis of the open-circuit fault of the different switching transistors of the single-phase half-bridge five-level inverter comprises:
using a data set of the labeled fusion image to serve as an input of the deep convolutional neural network, and dividing the data set of the labeled fusion image into a training set and a test set;
adopting the deep convolutional neural network to classify the fusion images of the different fault types, wherein the deep convolutional neural network is composed of an input layer, a plurality of convolutional layers, activation layers, pooling layers, and fully connected layers;
selecting a non-linear activation function and a non-linear loss function, wherein the deep convolutional neural network adopts a structure based on dynamic growth, determines an appropriate convolutional layer parameter, a pooling layer parameter, and a number of full connection layers using a network structure optimization method of increasing number of the convolutional layers/pooling layers and dropout technique, learns convolutional features of the fusion images of the same type of the open-circuit fault, and summarizes key common features; and
selecting a convolution kernel, and finally comparing fault diagnosis results of different deep convolutional neural networks.

14. The method according to claim 6, wherein performing the identification of the classification of the fusion image using the deep convolutional neural network, so as to realize the accurate diagnosis of the open-circuit fault of the different switching transistors of the single-phase half-bridge five-level inverter comprises:
using a data set of the labeled fusion image to serve as an input of the deep convolutional neural network, and dividing the data set of the labeled fusion image into a training set and a test set;
adopting the deep convolutional neural network to classify the fusion images of the different fault types, wherein the deep convolutional neural network is composed of an input layer, a plurality of convolutional layers, activation layers, pooling layers, and fully connected layers;
selecting a non-linear activation function and a non-linear loss function, wherein the deep convolutional neural network adopts a structure based on dynamic growth, determines an appropriate convolutional layer parameter, a pooling layer parameter, and a number of full connection layers using a network structure optimization method of increasing number of the convolutional layers/pooling layers and dropout technique, learns convolutional features of the fusion images of the same type of the open-circuit fault, and summarizes key common features; and
selecting a convolution kernel, and finally comparing fault diagnosis results of different deep convolutional neural networks.

15. A computer-readable storage medium, with a computer program stored thereon, wherein the computer program implements steps of the method for diagnosing the open-circuit fault of the switching transistors of the single-phase half-bridge five-level inverter according to claim 2 when the computer program is executed by a processor.

16. A computer-readable storage medium, with a computer program stored thereon, wherein the computer program implements steps of the method for diagnosing the open-circuit fault of the switching transistors of the single-phase half-bridge five-level inverter according to claim 3 when the computer program is executed by a processor.

17. A computer-readable storage medium, with a computer program stored thereon, wherein the computer program implements steps of the method for diagnosing the open-circuit fault of the switching transistors of the single-phase half-bridge five-level inverter according to claim 4 when the computer program is executed by a processor.

18. A computer-readable storage medium, with a computer program stored thereon, wherein the computer program implements steps of the method for diagnosing the open-circuit fault of the switching transistors of the single-phase half-bridge five-level inverter according to claim 5 when the computer program is executed by a processor.

19. A computer-readable storage medium, with a computer program stored thereon, wherein the computer program implements steps of the method for diagnosing the open-circuit fault of the switching transistors of the single-phase half-bridge five-level inverter according to claim 6 when the computer program is executed by a processor.

20. A computer-readable storage medium, with a computer program stored thereon, wherein the computer program implements steps of the method for diagnosing the open-circuit fault of the switching transistors of the single-phase half-bridge five-level inverter according to claim 7 when the computer program is executed by a processor.
